(19) United States
(12) Patent Application Publication
(10) Pub. No.: US 2025/0227890 A1
(43) Pub. Date: Jul. 10, 2025

(54) DEVICES, SYSTEMS AND METHODS RELATING TO UNDERFLOOR SERVER RACK COOLING SYSTEMS (UFSRCS) FOR DATA CENTER SERVER ROOMS AND THE LIKE

(71) Applicant: Global Integrated Flooring Solutions, Kentwood, MI (US)

(72) Inventors: Charles M. Brown, Greenwood Village, CO (US); Husam Ghazal, Mississauga (CA)

(73) Assignee: Global Integrated Flooring Solutions, Kentwood, MI (US)

(21) Appl. No.: 18/785,187

(22) Filed: Jul. 26, 2024

Related U.S. Application Data
(60) Provisional application No. 63/617,506, filed on Jan. 4, 2024.
(60) Provisional application No. 63/617,524, filed on Jan. 4, 2024.

(51) Int. Cl. H05K 7/20

(52) U.S. Cl. CPC H05K 7/20745

(57) ABSTRACT

An underfloor server rack cooling system (UFSRCS) for a data center server room having a raised access floor (RAF), the UFSRCS having, in the RAF, a hot air intake port located at a hot air back side of a server rack and a cold air output port located on an opposed cool air side of the server rack, wherein a fan and a cooling coil of the UFSRCS are under the RAF and between the input port and the output port.

### CROSS-REFERENCE TO RELATED APPLICATIONS

The present application claims the benefit of copending U.S. Provisional Patent Application Ser. No. 63/617,506, filed Jan. 4, 2024, and claims the benefit of copending U.S. Provisional Patent Application Ser. No. 63/617,524, filed Jan. 4, 2024, both of which are presently pending, which applications are incorporated herein by reference in their entirety.

### BACKGROUND

Traditional central data center cooling systems have local units that provide cooling that is controlled locally to match the server temperature control needs but not on a highly selective basis where a single or selected group of cooling systems selectively and controllably cools a single or selected group of server racks, server pods, etc. Such server temperature control needs vary at the individual server/server rack level and over time.

There has gone unmet a need for devices, systems, methods, etc., for the following issues, each of which is not adequately addressed by traditional HVAC/cooling systems:
a) the local components do not compete for floor space because they are under the floor;
b) the system is easily installed due to the small size of each component and the manner each component is integrated into the flooring structure;
c) the system can be easily serviced, for example by simply removing a raised access floor (RAF) or other floor panel above the component;
d) the system allows cooling capacity to be acquired and installed modularly as a data center adds servers and server racks, rather than investing in maximum center-wide capacity before it is needed; and
e) The system provides lower energy usage for example due to cooling and moving smaller volumes of air than traditional centralized full-sized cooling systems.

The present devices, systems and methods, etc., provide solutions to one or more of these needs, and/or one or more other advantages.

### SUMMARY

The present systems, devices and methods, etc., are directed to providing cooling capacity to rooms and buildings having heat-intensive or cooling-intensive requirements, particularly data centers, data center server rooms or server farms, or server rack(s) where the cooling is generated, controlled and distributed by one of the cooling units herein to a selected cooling site, which can be as few as one server pod or one server rack. In other words, the cooling unit and cooling capacity is individually controllable in operable connection with a single server rack (typically a 1:1 ratio; more than 1:1 on either side, typically up to 1:3 or 3:1, can be implemented if desired). This allows the amount of cooling provided to a rack to vary with the amount required by the rack that the corresponding unit serves at a fully localized level. It also provides the ability to add additional racks and coolers on a fully modular basis, e.g., placing additional server racks and coolers next to (typically side-by-side against) the initial rack-cooler combination system. The systems, etc., can also utilize piping that can provide cooling liquids to additional liquid based server cooler systems without adding significant additional piping infrastructure. As multiple one-to-one coolers are deployed, they provide redundancy for each other. This can also be provided at the local server or group of servers level. By localizing the cooling and controls, far less air is treated and moved than with conventional solutions. These structures and advantages can enhance energy and cost efficiency in some embodiments while simultaneously ensuring individual servers are maintaining their optimal operating temperatures.

In some embodiments, the fan and the cooling coil are operably connected, for example by HVAC ducting, and are also located remote from each other. For example, the fan and cooling coil can be located at opposed sides of their corresponding server rack. This allows the fan to draw-in hot air from the back side of the server rack then transfer it to be cooled where cold air is needed (the front side of the servers). This design allows the critical cooling equipment components (fan and coil) to be easily installed and easily serviced while conveniently located under the floor. The current aspects and embodiments can also eliminate the need for large centralized cooling equipment.

The present systems, devices and methods, etc., provide underfloor server rack cooling systems (UFSRCS) for a data center server room, including portions of server rooms, or any full room or significant part of a room containing server racks, server pods, etc., as well as building having such server rooms. The UFSRCS comprises at least one a hot air intake port for a raised access floor (RAF) of the data center server room, with the hot air intake being located to capture air coming out of a hot air back side of a server rack and also comprising an operably connected cold air output port for the RAF and located on an opposed cool air side of the server rack to supply cool air to the server rack. The UFSRCS also comprises a fan and a cooling coil, which are disposed between and operably connected in-line to the input port and the output port. The UFSRCS is sized and configured to fit within an underfloor space between an upper surface of the RAF and a subfloor with none of the UFSRCS extending more than an insignificant amount above a top surface of the RAF floor.

In some aspects, the present systems, devices and methods, etc., at least one of the hot air intake port or the cold air output port comprises at least one RAF floor attachment element for holding the hot air intake port or cold air output port to the RAF floor at a desired location in the RAF. Exemplary attachment elements include flanges, lips, screws, bolts, etc., and the RAF floor attachment element extends no more than an insignificant amount above a top surface of the RAF floor. In some embodiments, the RAF floor attachment element extends no more than about 5 mm, 3 mm or 1 mm above a top surface of the RAF floor. The fan can be operably connected to but separate from the cooling coil, and the fan can be located in the underfloor space at one side of the server rack and the cooling coil can be located in the underfloor space at an opposed side of the server rack.

In some aspects, the hot air intake port can be located entirely at a hot air back side of a server rack and not under the server rack, for example where the server-side edge of the hot air intake port abuts a hot air back side of the server rack (i.e., the server-side edge of the hot air intake port is touching or directly under the server rack and is not under the server rack. The cold air output port can be located entirely at the opposed cool air side of the server rack and not under the server rack. At least one of the hot air intake port or the cold air output port comprises at least one RAF floor attachment element for holding the hot air intake port or cold air output port to the RAF floor at a desired location in the RAF. The fan can be operably connected to but separate from the cooling coil, and wherein the fan can be located in the underfloor space at one side of the server rack and the cooling coil can be located in the underfloor space at an opposed side of the server rack.

The embodiments herein include data center server rooms, including portions of server rooms, or any full room or significant part of a room containing server racks, server pods, etc., as well as building having such server rooms, that contain the UFSRCS discussed herein. The data center server rooms, buildings, etc., further can comprise the UFSRCS under the RAF, as well as controllers operably connected to the UFSRCS to selectively control temperature activity of the UFSRCS in coordination with at least one server rack, server pod or other selected heat-intensive in-room component, within the data center server room.

In some embodiments, the data center server room contains a plurality of server racks in a server rack pod and a plurality of UFSRCS, and wherein an operably connected controller selectively controls the temperature activity of the plurality of UFSRCS in coordination with the plurality of server racks. In some embodiments the controller selectively controls the temperature activity of the plurality of UFSRCS in coordination with at least one of a selected server rack, a selected group of server racks, or a selected server pod.

These and other aspects, features and embodiments are set forth within this application, including the following Detailed Description and attached drawings. In addition, various references are set forth herein, including in the Cross-Reference To Related Applications, that discuss certain systems, apparatus, methods and other information; all such references are incorporated herein by reference in their entirety and for all their teachings and disclosures, regardless of where the references may appear in this application.

### BRIEF DESCRIPTION OF THE DRAWINGS

FIG. 1 depicts a side plan stylized view of a server room and an underfloor server rack cooling system (UFSRCS) as discussed herein.

FIG. 2 depicts a top plan stylized view of an underfloor server rack cooling system (UFSRCS) as discussed herein.

FIG. 3 depicts a depicts a top plan stylized view of a server room and an underfloor server rack cooling system (UFSRCS) as discussed herein.

FIG. 4 depicts a top plan stylized view of a server room and an underfloor server rack cooling system (UFSRCS) as discussed herein.

FIG. 5 depicts a side plan stylized view of a server room and an underfloor server rack cooling system (UFSRCS) as discussed herein.

FIG. 6 depicts a side plan stylized view of a server room and an underfloor server rack cooling system (UFSRCS) as discussed herein.

FIG. 7 depicts a side plan stylized view of a server room and an underfloor server rack cooling system (UFSRCS) as discussed herein.

FIG. 8 depicts a side plan stylized view of a server room and an underfloor server rack cooling system (UFSRCS) in combination with an underfloor cubic support system (UFCSS) as discussed herein.

FIG. 9 depicts a side plan stylized view of a server room and an underfloor server rack cooling system (UFSRCS) in combination with an underfloor cubic support system (UFCSS) as discussed herein.

### DETAILED DESCRIPTION

The present devices, systems and methods, etc., provide approaches able to provide highly tailored and easily adjustable cooling to server racks and server pods within a data center.

The underfloor server rack cooling system (UFSRCS) for a data center server room (including portions of server rooms, or any full room or significant part of a room containing server racks that would benefit from the easily installed, highly effective systems, etc., herein, as well as buildings containing such rooms) provide underfloor systems, typically entirely under the floor except possibly for unobtrusive elements such as flanges such as protruded ridges, lips or rims to assist connection of the upper elements of the UFSRCS to RAF flooring or other connection elements. The UFSRCS flow air through the servers and cooling system, with the servers heating the air as the air moves from front to back through the servers. The fan of the cooling system draws in the hot air, pushes it under the server through the separated cooling coil then back up directly in front of the server. This creates a circular and local track for the air. Vanes, ducting, hot or cold air containment structures, etc., can be provided if desired, yet one advantage of the current system is that such additional components can be omitted. The cooling coil and fan can be separated so they can be easily installed and serviced in a component fashion, all while under the floor if desired, thereby delivering advantages such as economizing on floor space. The two components (fan and cooling coil) can also be controlled locally based on temperature sensors at, in or near the servers, which sensors can determine the amount of cold air required to maintain desired/optimal operating temperatures separately for any desired unit of computing capacity, for example for each server unit in the server rack, for each server rack in a server pod, for a group of server racks in a pod, or otherwise as desired. This can be advantageous because such cooling requirements change between individual servers and over time.

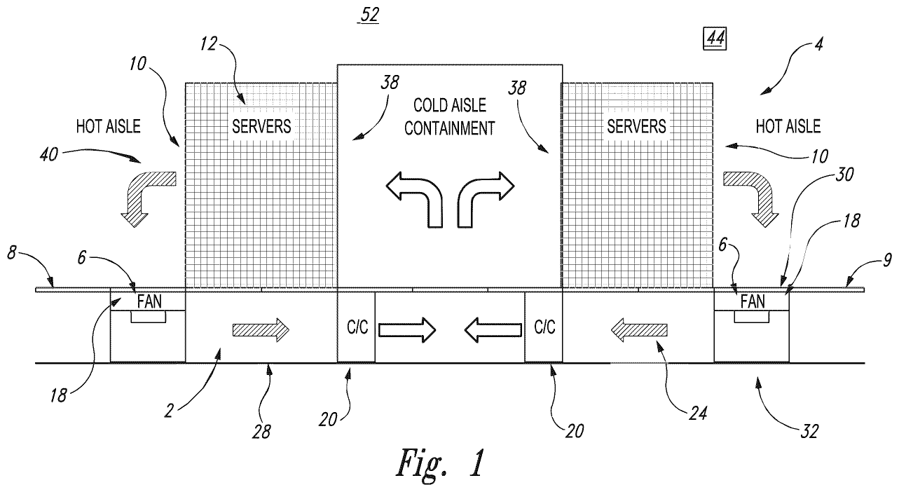

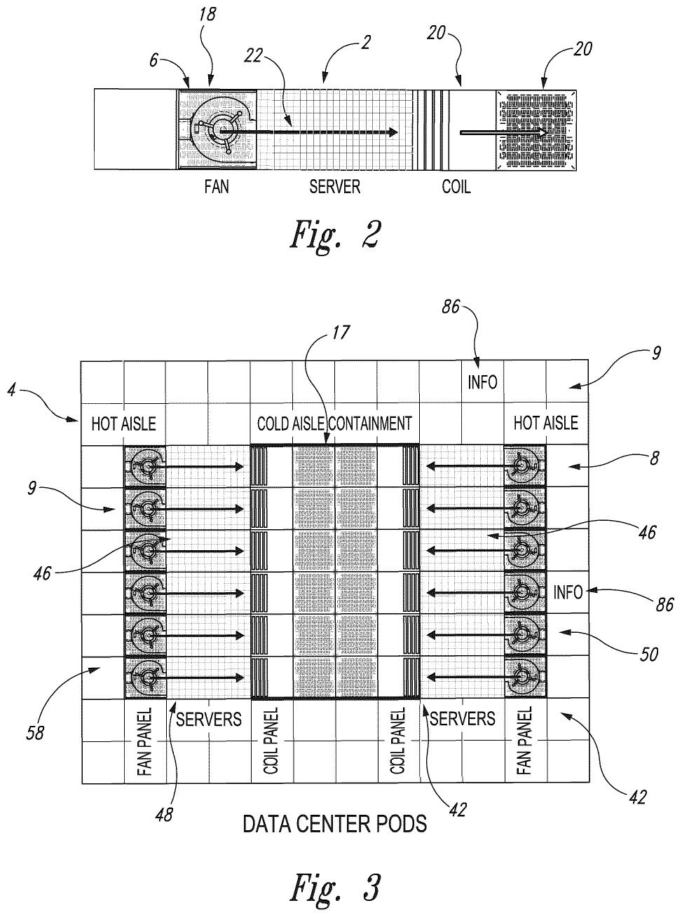

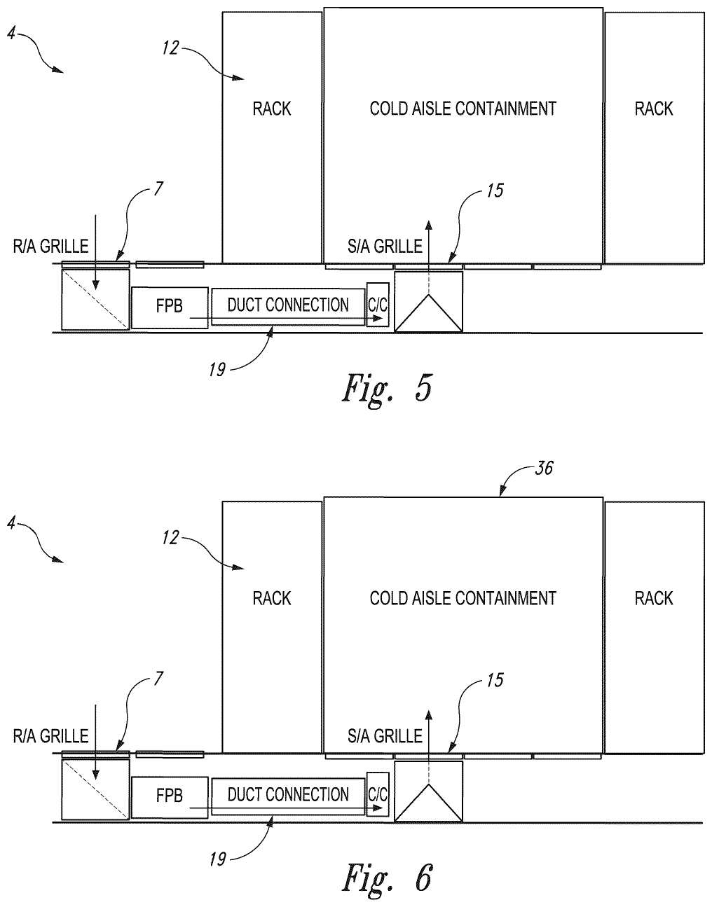

Turning to the Figures, FIGS. 1 to 8 show a UFSRCS 2 for a data center server room 4 as discussed herein. For example in FIG. 1 as well as several other Figures, the UFSRCS 2 comprises a hot air intake port 6 for a raised access floor (RAF) 8 of the data center server room 4. The hot air intake port 6 is located at a hot air back side 10 of a server rack 12 in the data center server room 4. The hot air intake port 6 can be located entirely outside of the footprint (i.e., sides) of the server rack, i.e., entirely at a hot air back side of the server rack and not under the server rack, and in some embodiments a server-side edge of the hot air intake port 6 abuts the back edge of the server rack. In other words, in certain embodiments the hot air intake port 6 begins where the back edge of the server 12 ends. A cold air output port 14 for the RAF 8 is located on an opposed cool air side 16 of the server rack 12, and a fan 18 and a cooling coil 20 of the UFSRCS 2 disposed between and operably connected in-line 22 to the input port and the output port, the UFSRCS 2 sized and configured to fit within an underfloor space 24 between an upper surface 9 of the RAF 8 and a subfloor 28 with none of the UFSRCS 2 extending more than an insignificant amount above a top surface of the RAF 8 floor.

In some embodiments, at least one of the hot air intake port 6 or the cold air output port 14 comprises at least one RAF floor holding element 30 for holding the hot air intake port 6 or cold air output port 14 to the RAF 8 floor at a desired location 32 in the RAF 8. The attachment element can include holding the port in-place by a fastener, a friction fit, physical interference fit, floating free held by gravity, or otherwise as desired. In some embodiments, the RAF floor holding element 30 can extend an insignificant amount above a top surface of the RAF floor.

In some embodiments, the RAF floor attachment elements 30 extend no more than about 5 mm, 3 mm or 1 mm above a top surface 9 of the RAF floor. The at least one RAF floor holding element 30 is a flange such as a lip, extended edge or rim, and can be vertical or horizontal, or shaped or angled otherwise (such as a semi-loop) as desired.

Fan 18 is operably connected to and can be unitary with or separate from the cooling coil 20, for example where the fan 18 is located in the underfloor space 24 at one side 40 of the server rack 12 and the cooling coil 20 is located in the underfloor space 24 at an opposed side 38 of the server rack 12. The fan 18 and cooling coil 20 can be located in other locations within the underfloor plenum as desired (typically wholly within but sometimes mostly within).

In the Figures, UFSRCS 2 comprises a hot air intake port 6 for a RAF 8 of the data center server room 4 and a cold air output port 14 for the RAF 8 and located on an opposed cool air side 16 of the server rack 12, and a fan 18 and a cooling coil 20 of the UFSRCS 2 disposed between and operably connected in-line 22 to the input port and the output port. Operably connected in-line 22 generally indicates that the UFSRCS 2 accepts hot air from the hot air side 10 of the server rack 12 for example through the hot air intake port 6, cools it, and transmit it at a desired, selected airflow rate to and through the cold air output port 14. In certain embodiments, the hot air intake port 6 is located entirely at a hot air back side 10 of a server rack 12 and not under the server rack 12. The cold air output port 14 can be located entirely at the opposed cool air side 16 of the server rack 12 and not under the server rack 12. In some embodiments, at least one of the hot air intake port 6 or the cold air output port 14 comprises at least one RAF floor holding element 30 for holding the hot air intake port 6 or cold air output port 14 to the RAF floor at a desired location 32 in the RAF 8. The hot air intake port 6 or cold air output port 14 can be covered by return air grille 7 or supply air grille 15, respectively.

In some aspects, such as in FIGS. 1 and 3 through 8, the current embodiments include data center server rooms 4 having a server rack 12 within the room sitting atop 42 a RAF 8 with the UFSRCS 2 in the underfloor plenum, and typically also contains, either within its walls or vial operable connection to a remote controller, a controller 44 operably connected to the UFSRCS 2 to selectively control temperature activity of the UFSRCS 2 in coordination with at least one server rack 12 within the data center server room 4.

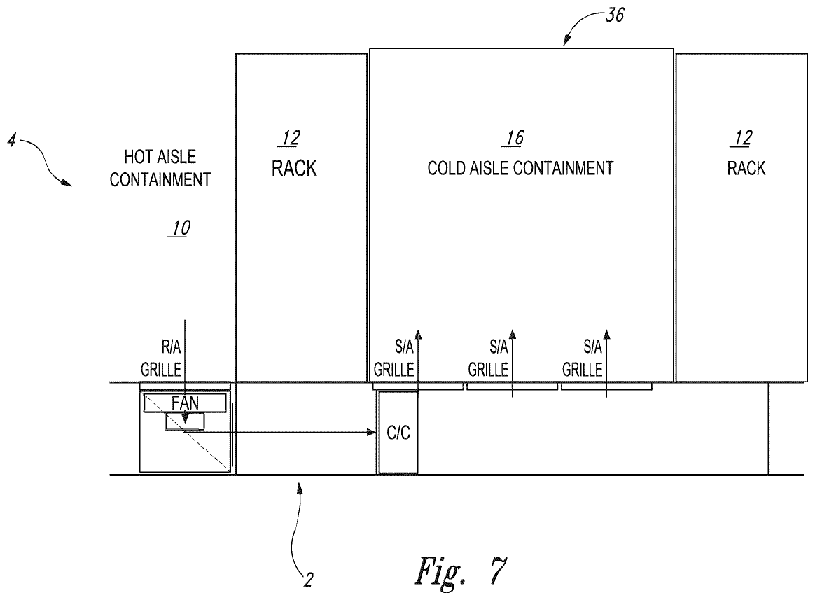

The data center server room 4 can contains a plurality of server racks 46 in a server rack 12 pod and a corresponding plurality of UFSRCS 2, and wherein the controller 44 selectively controls the temperature activity of the plurality of UFSRCS 2 in coordination with the plurality of server racks 46, for example in a 1:1 ratio 50 of one UFSRCS 2 to one server rack 12. Other ratios can also be implemented such as 1:2, 2:1, 1:3, 3:1, etc. In certain embodiments, as shown in FIGS. 1 and 3-8, the data center server room 4 does not have any hot air airflow containment structure within walls of the data center server room 4 that confines or directs hot air from the hot air back side 10 of the server rack 12 to the UFSRCS 2. Examples of such airflow containment structure include plastic sheeting or drapes that hang from the ceiling or from support frames or the server rack itself. For comparison, a cold air airflow containment system or structure 36 is shown in FIGS. 3 and 7.

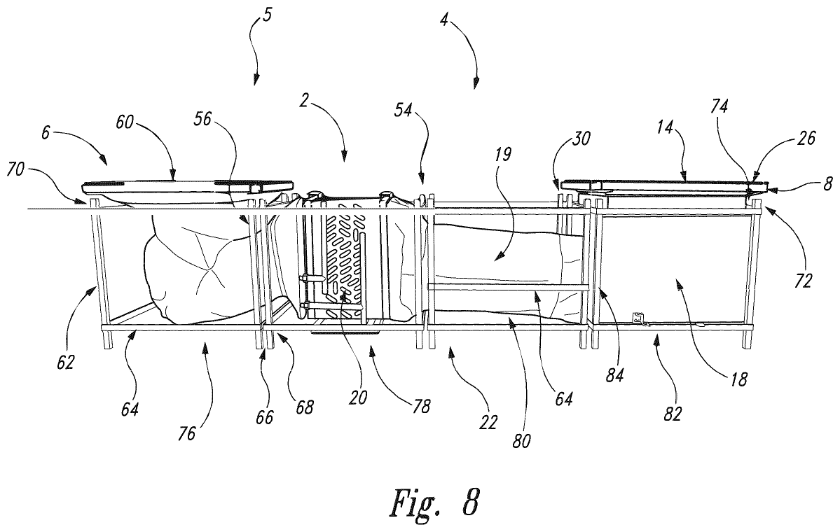

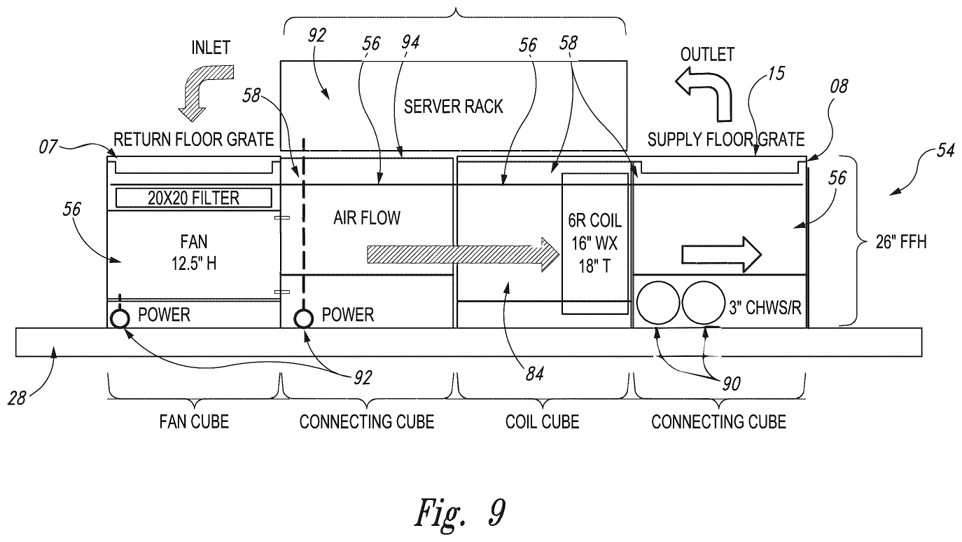

As shown for example in FIGS. 8 and 9 (air flow reversed compared to FIG. 8), the data center server room 4 further can comprise at least one underfloor cubic support system (UFCSS) 54 between the raised access floor (RAF) 8 and a subfloor 28. The UFCSS 54 comprises a UFCSS 3-D frame 56 connected to (attached, floating, etc.) and supporting a raised access floor panel (RAF panel) 58 of the RAF 8 to provide a UFCSS 3-D frame-RAF panel unit 84, wherein:
the UFCSS 3-D frame holds and supports the RAF panel above the subfloor 28 and the UFCSS 3-D frame comprises at least 3 vertical corner posts 62 connected to each other by cross-support bars 64, with each corner post 62 comprising a foot 66 at a lower end 68 configured to contact the subfloor 28 and a pedestal head 70 at an upper end 72 attached or otherwise held to the RAF panel and if desired a variable height adjustment element 74 to raise and lower the pedestal head 70 relative to the foot 66, and
the RAF panel comprises at least 3 sides and the UFCSS 3-D frame does not extend beyond any of the sides of the RAF panel.

In some embodiments, such as in FIGS. 8 and 9, including kit and system embodiments, a UFSRCS can be contained in one or more UFCSS frames 56, for example a first UFCSS 3-D frame 82 that holds the hot air intake port 6 and a second UFCSS 3-D frame 76 holds cold air output port 14. The fan 18 and the cooling coil 20 can be held in such first and/or second UFCSS 3-D frame, or third UFCSS 3-D frame 80 can hold the cooling coil 20 and a fourth UFCSS 3-D frame 82 holds the fan 18. In some embodiments, a separate UFCSS 3-D frame, which can be third UFCSS 3-D frame 80 (typically where it does not hold the cooling coil 20 or fan 18) or additional UFCSS 3-D frames, holds duct connection 19 connectable to other UFCSS 3-D frames to connect disparate components of the UFSCRS. The various UFCSS 3-D frames typically have an RAF panel, an air duct grille and or other data center server room components atop the UFCSS 3-D frames.

In FIGS. 8 and 9 (air flow reversed compared to FIG. 8), the UFCSS can be implemented in a data center server room 04 within a building 05 and can further comprise at least one underfloor server rack cooling system (UFSRCS) 02. UFSRCS 02 in the Figures is held within consecutive UFCSS 3-D frames 6 56, and under the raised access floor (RAF) 08 and above a subfloor 28. UFCSS 02 comprises UFCSS 3-D frames 56 connected to and supporting a RAF panel 58 of the RAF 08 to provide a UFCSS 3-D frame-RAF panel unit 84. In the embodiment shown, UFCSS 3-D frames 56 hold and support the RAF panels 58 above the subfloor 28 and the UFCSS 3-D frames 56 comprise 4 vertical corner posts 62 connected to each other by cross-support bars 64, with each corner post 62 comprising a foot 66 at a lower end 68 configured to contact the subfloor 28 and a pedestal head 70 at an upper end 72 attached to the RAF panel and a variable height adjustment element 74 to raise and lower the pedestal head 70 relative to the foot 66, and the complementary RAF panel comprises 4 complementary sides and the UFCSS 3-D frame 56 does not extend beyond any of the sides of the RAF panel.

In some embodiments, including kit and system embodiments, for example in FIGS. 8 and 9, the UFCSS 02 contains a first UFCSS 3-D frame 82 that holds the hot air intake port 08 and a second UFCSS 3-D frame 76 holds cold air output port 06. The fan 18 and the cooling coil 20 can be held in such first and/or second UFCSS 3-D frame, or third UFCSS 3-D frame 80 can hold the cooling coil 20 and a fourth UFCSS 3-D frame 82 holds the fan 18. In some embodiments, a separate UFCSS 3-D frame, which can be a third UFCSS 3-D frame 80 (typically if it does not hold the cooling coil 20 or fan 18, holds a duct connection 19 connectable to other UFCSS 3-D frames to connect disparate components of the UFSCRS. The various UFCSS 3-D frames typically have an RAF panel 58, and air duct grilles 07, 15 and other data center server room components atop the UFCSS 3-D frames. As shown in FIG. 9, the UFCSS 54 can also hold other elements and structures, for example water pipes 90 and electric wiring 92, and can contain instructions 94 or other imaging describing the items underneath/within the RAF panel or UFCSS 3-D frame.

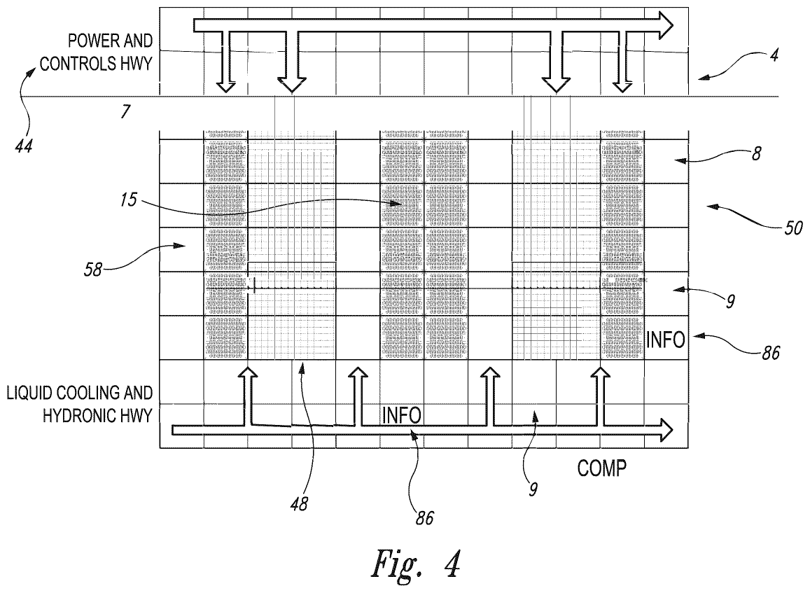

FIGS. 1 and 4 also depict controller 44 configured to selectively UFSRCS 2 to selectively provide need-dependent cooling for a selected complementary server rack 12. A controller 44 can be configured, for example containing computer-implemented programing, databases, artificial intelligence, etc., to selectively operate the UFSRCS to selectively provide need-dependent cooling as desired, for example provided independently for each computer, or server or server rack in a server pod 48 of server racks 40, or for each server pod 48 in a data center server room 4. Such needs can be selected to provide cooling at a 1:1 ratio, 2:1 ratio or otherwise as desired.

FIGS. 3 and 4 also depict computer server rooms 4 having a RAF 8 atop traditional pedestal support systems in FIG. 3 and UFCSS systems as also shown in FIGS. 8 and 9. As can be seen in FIGS. 3 and 4, the RAF floor itself does not necessarily show any difference to users above the floor. Also in FIGS. 3 and 4, the server room 4 in FIG. 3 includes cold aisle containment 17, which can also be referred to as a cold air airflow containment system, whereas there is no cold aisle containment in FIG. 4. Examples of such cold air airflow containment structures include plastic sheeting or drapes that hang from the ceiling or from support frames or the server rack itself.

Further, the RAF panels, including for example peripheral RAF panels 9 (panels at an outer area of the overall floor, e.g., those abutting a wall of the room), can have information 86 such as printing, etching or other printed imagery or words including digital printing. Such information can include words, maps, diagrams, or other useful information about the components maintained below a given RAF panel or RAF panel unit, or group of RAF panels or RAF panel units, and can be printed, etched, mapped, contained in a decal, or otherwise permanently or temporarily imposed on the RAF panel unit. Such information 86 can convey key components, wires, or pipes underneath the given raised floor panel and/or as a schematic for several RAF panels or even the room as a whole. Thus, such information can describe components contained under the RAF floor including even within a particular UFCSS 3-D frame or group of frames, including under a given complementary UFCSS 3-D frame-RAF panel unit. This can create a visual map of the floor easily seen and understood from above the floor. Thus, printing an image or other instructions on a given UFCSS RAF panel or UFCSS 3-D frame of what lies underneath/within can help a variety of issues including reducing the problem of future workers locating the components under the RAF. This aspect applies to conventional flooring systems as well, including for example printing or otherwise installing such information on the top RAF surfaces mounted on traditional pedestal systems, such as in FIG. 3. This printing approach can be useful where traditional pedestal systems are used in combination with UFCSS systems in a given room. This aspect applies to conventional rooms, including conventional server rooms lacking the current UFSRCS systems, as well as non-server rooms having RAF floors composed of an array of RAF floor panels.

The current UFSRCS systems, devices and methods, etc., have one or more advantages compared to traditional centralized cooling units. For example, traditional units typically require routing of air throughout the entire data center room. In some embodiments, such traditional systems can be augmented by and/used in combination with the UFSRCS herein, for example when the current UFSRCS units are located in the row of server racks with their respective fans and coils in the same “row cooler” unit.

Various aspects, features and embodiments are set forth within this application, including this Summary and Detailed Description and attached drawings. Unless expressly stated otherwise or clear from the context, all embodiments, aspects, features, etc., can be mixed and matched, combined and permuted in any desired manner,

All terms used herein are used in accordance with their ordinary meanings unless the context or definition clearly indicates otherwise. Also unless expressly indicated otherwise, in the specification the use of “or” includes “and” and vice-versa. Non-limiting terms are not to be construed as limiting unless expressly stated, or the context clearly indicates, otherwise (for example, “including,” “having,” and “comprises” typically indicate “including without limitation”). Singular forms, including in the claims, such as “a,” “an,” and “the” include the plural reference unless expressly stated, or the context clearly indicates, otherwise.

Unless otherwise stated, adjectives herein such as “substantially” and “about” that modify a condition or relationship characteristic of a feature or features of an embodiment, indicate that the condition or characteristic is defined to within tolerances that are acceptable for operation of the embodiment for an application for which it is intended.

The scope of the present devices, systems and methods, etc., includes both means plus function and step plus function concepts. However, the claims are not to be interpreted as indicating a “means plus function” relationship unless the word “means” is specifically recited in a claim, and are to be interpreted as indicating a “means plus function” relationship where the word “means” is specifically recited in a claim. Similarly, the claims are not to be interpreted as indicating a “step plus function” relationship unless the word “step” is specifically recited in a claim, and are to be interpreted as indicating a “step plus function” relationship where the word “step” is specifically recited in a claim.

From the foregoing, it will be appreciated that, although specific embodiments have been discussed herein for purposes of illustration, various modifications may be made without deviating from the spirit and scope of the discussion herein. Accordingly, the systems and methods, etc., include such modifications as well as all permutations and combinations of the subject matter set forth herein and are not limited except as by the appended claims or other claim having adequate support in the discussion and figures herein.

What is claimed is:

1. An underfloor server rack cooling system (UFSRCS) for a data center server room, the UFSRCS comprising a hot air intake port for a raised access floor (RAF) of the data center server room and located at a hot air back side of a server rack in the data center server room and a cold air output port for the RAF and located on an opposed cool air side of the server rack, and a fan and a cooling coil of the UFSRCS disposed between and operably connected in-line to the input port and the output port, the UFSRCS sized and configured to fit within an underfloor space between an upper surface of the RAF and a subfloor with none of the UFSRCS extending more than an insignificant amount above a top surface of the RAF floor.

2. The underfloor server rack cooling system (UFSRCS) of claim 1 wherein at least one of the hot air intake port or the cold air output port comprises at least one RAF floor attachment element for holding the hot air intake port or cold air output port to the RAF floor at a desired location in the RAF, the RAF floor attachment element extending an insignificant amount above a top surface of the RAF floor.

3. The underfloor server rack cooling system (UFSRCS) of claim 2 wherein the at least one RAF floor attachment element extends no more than about 3 mm above a top surface of the RAF floor.

4. The underfloor server rack cooling system (UFSRCS) of claim 1, wherein the at least one RAF floor attachment element is a flange.

5. The underfloor server rack cooling system (UFSRCS) of claim 1 wherein the fan is operably connected to but separate from the cooling coil, and wherein the fan is located in the underfloor space at one side of the server rack and the cooling coil is located in the underfloor space at an opposed side of the server rack.

6. An underfloor server rack cooling system (UFSRCS) for a data center server room, the UFSRCS comprising a hot air intake port for a raised access floor (RAF) of the data center server room and a cold air output port for the RAF and located on an opposed cool air side of the server rack, and a fan and a cooling coil of the UFSRCS disposed between and operably connected in-line to the input port and the output port, wherein the hot air intake port is located entirely at a hot air back side of a server rack and not under the server rack.

7. The underfloor server rack cooling system (UFSRCS) of claim 6 wherein a server-side edge of the hot air intake port abuts a hot air back side of the server rack and is not under the server rack.

8. The underfloor server rack cooling system (UFSRCS) of claim 6 wherein the cold air output port is located entirely at the opposed cool air side of the server rack and not under the server rack.

9. The underfloor server rack cooling system (UFSRCS) of claim 8 wherein at least one of the hot air intake port or the cold air output port comprises at least one RAF floor attachment element for holding the hot air intake port or cold air output port to the RAF floor at a desired location in the RAF.

10. The underfloor server rack cooling system (UFSRCS) of claim 1 wherein the fan is operably connected to but separate from the cooling coil, and wherein the fan is located in the underfloor space at one side of the server rack and the cooling coil is located in the underfloor space at an opposed side of the server rack.

11. (canceled)

12. (canceled)

13. (canceled)

14. The data center server room of claim 10 wherein the data center server room does not have any hot air airflow containment system within walls of the data center server room that confines or directs hot air from the hot air back side of the server rack to the UFSRCS.

15. The data center server room of claim 10 wherein the data center server room does not have any cold air airflow containment system within walls of the data center server room that confines or directs cold air from the UFSRCS to the cold air front side of the server rack.

16. A building containing the underfloor server rack cooling system kit (UFSRCS) of claim 1.

17. A building comprising the data center server room of claim 11.

18. An underfloor server rack cooling system kit (UFSRCS kit) comprising an underfloor server rack cooling system (UFSRCS) for a data center server room, the UFSRCS comprising a hot air intake port for a raised access floor (RAF) for the data center server room to intake hot air from a hot air back side of a server rack and a cold air output port for the RAF to output cooled air at an opposed cool air side of the server rack, and a fan and a cooling coil of the UFSRCS, and at least one of a) instructions for use of the UFSRCS kit or b) packaging materials for the UFSRCS kit.

19-41. (canceled)

42. The underfloor server rack cooling system (UFSRCS) of claim 6 wherein the fan is operably connected to but separate from the cooling coil, and wherein the fan is located in the underfloor space at one side of the server rack and the cooling coil is located in the underfloor space at an opposed side of the server rack.

43. (canceled)

44. The data center server room of claim 11 wherein the data center server room does not have any hot air airflow containment system within walls of the data center server room that confines or directs hot air from the hot air back side of the server rack to the UFSRCS.

45. The data center server room of claim 12 wherein the data center server room does no Et have any hot air airflow containment system within walls of the data center server room that confines or directs hot air from the hot air back side of the server rack to the UFSRCS.

46. The data center server room of claim 13 wherein the data center server room does not have any hot air airflow containment system within walls of the data center server room that confines or directs hot air from the hot air back side of the server rack to the UFSRCS.

47. The data center server room of claim 11 wherein the data center server room does not have any cold air airflow containment system within walls of the data center server room that confines or directs cold air from the UFSRCS to the cold air front side of the server rack.

48. The data center server room of claim 12 wherein the data center server room does not have any cold air airflow containment system within walls of the data center server room that confines or directs cold air from the UFSRCS to the cold air front side of the server rack.

49. The data center server room of claim 13 wherein the data center server room does not have any cold air airflow containment system within walls of the data center server room that confines or directs cold air from the UFSRCS to the cold air front side of the server rack.

50. A building containing the underfloor server rack cooling system kit (UFSRCS) of claim 6.

51. A building comprising the data center server room of claim 12.

52. A building comprising the data center server room of claim 13.

53. A building comprising the data center server room of claim 14.

54. A building comprising the data center server room of claim 15.

55-58. (canceled)
